(19) United States
(12) Patent Application Publication
(10) Pub. No.: US 2014/0097447 A1
(43) Pub. Date: Apr. 10, 2014

(54) SEMICONDUCTOR DEVICE AND METHOD OF MANUFACTURING THE SAME

(71) Applicant: HYUNDAI MOTOR COMPANY, Seoul (KR)

(72) Inventors: Jong Seok Lee, Suwon (KR); Kyoung-Kook Hong, Hwaseong (KR)

(73) Assignee: Hyundai Motor Company, Seoul (KR)

(21) Appl. No.: 13/709,905

(22) Filed: Dec. 10, 2012

(30) Foreign Application Priority Data
Oct. 4, 2012 (KR) 10-2012-0110026

(51) Int. Cl. H01L 29/16; H01L 29/66; H01L 29/78

(52) U.S. Cl. CPC H01L 29/1608; H01L 29/7827; H01L 29/66068
USPC 257/77; 438/270

(57) ABSTRACT

Disclosed herein is a semiconductor device and method of manufacturing the semiconductor, including an n type buffer layer disposed on a first surface of an n+ type silicon carbide substrate, an n− type epitaxial layer disposed on the n type buffer layer, a first type of trench disposed on each side of a second type of trench, wherein the trenches are disposed in the n− type epitaxial layer, an n+ region disposed on the n− type epitaxial layer, a p+ region disposed in each first type of trench, a gate insulating layer disposed in the second trench, a gate material disposed on the gate insulating layer, an oxidation layer disposed on the gate material, a source electrode disposed on the n+ region, oxidation layer, and p+ region, and a drain electrode disposed on a second surface of the n+ type silicon carbide substrate.

### CROSS-REFERENCE TO RELATED APPLICATION

This application claims priority to and the benefit of Korean Patent Application No. 10-2012-0110026 filed in the Korean Intellectual Property Office on Oct. 4, 2012, the entire contents of which are incorporated herein by reference.

### BACKGROUND OF THE INVENTION

(a) Field of the Invention

The present invention relates to a semiconductor device including silicon carbide (SiC), and a method of manufacturing the same.

(b) Description of the Related Art

In response to the recent trend of enlarging the size and capacity of application equipment, a demand for a semiconductor device for electric power, having a high breakdown voltage, a high current, and a high-speed switching characteristic has increased.

Particularly, the semiconductor device for electric power needs to have low on-resistance or low saturated voltage to allow a very large current to flow and to reduce a power loss in a continuity state. Further, a characteristic having an inverse direction high voltage of a p-n junction, applied to both ends of the semiconductor device is required for electric power in an off state or when a switch is turned off, that is, a high breakdown voltage. The p-n junction is formed at a boundary between the p-type and the n-type semiconductor. The device is the most general electric field effect transistor in a metal oxide semiconductor field effect transistor (MOSFET) digital circuit and an analog circuit among the semiconductor devices for electric power.

In the MOSFET using silicon carbide (SiC), the contact between a silicon oxidation layer acting as a gate insulating layer and silicon carbide may be poor, affecting a flow of an electron current passing through a channel formed in a lower end of the silicon oxidation layer to significantly reduce electron mobility. Particularly, when a trench gate is formed, an etching process is required, and thus poorer electron mobility is exhibited.

The above information disclosed in this section is only for enhancement of understanding of the background of the invention and therefore it may contain information that does not form the prior art that is already known in this country to a person of ordinary skill in the art.

### SUMMARY OF THE INVENTION

The present invention has been made in an effort to improve electron mobility in a channel in a silicon carbide MOSFET to which a trench gate is applied.

An exemplary embodiment of the present invention provides a semiconductor device including: an n type buffer layer disposed on a first surface of an n+ type silicon carbide substrate; an n− type epitaxial layer disposed on the n type buffer layer; a first type of trench, including two trenches, and a second type of trench, including one trench, disposed in the n− type epitaxial layer; an n+ region disposed on the n− type epitaxial layer; a p+ region disposed in the first type of trench; a gate insulating layer disposed in the second type of trench; a gate material disposed on the gate insulating layer; an oxidation layer disposed on the gate material; a source electrode disposed on the n+ region, the oxidation layer, and the p+ region; and a drain electrode disposed on a second surface of the n+ type silicon carbide substrate, in which the first type of trenches are disposed at both sides of the second type of trench, and each first type of trench is separated from the second type of trench.

A space between each first type of trench and the second type of trench may be 0.3 μm to 1 μm. A space between a lower surface of each first trench and the lower surface of the n+ region may be 1.5 μm or more. The n+ regions may be disposed at both sides of the second type of trench.

Another exemplary embodiment of the present invention provides a method of manufacturing a semiconductor device, including: forming an n type buffer layer on a first surface of an n+ type silicon carbide substrate; forming an n− type epitaxial layer on the n type buffer layer; forming a plurality of trenches, including a first type of trench and a second type of trench, in the n− type epitaxial layer; injecting p+ ions into the first type of trenches to form a p+ region; injecting n+ ions into the n− type epitaxial layer to form a first n+ region; etching a portion of the n− type epitaxial layer formed through the first n+ region to form the second type of trench; forming a gate insulating layer in the second type of trench; forming a gate material on the gate insulating layer; forming an oxidation layer on the gate material; forming a drain electrode on a second surface of the n+ type silicon carbide substrate; and forming a source electrode on the p+ region, an n+ region, and the oxidation layer, in which the first type of trenches and the second type of trench are separated from each other, and the first trenches are disposed at both sides of the second type of trench.

The forming of the first type of trenches may further include etching a portion of the first n+ region to form the n+ region.

As described above, according to the exemplary embodiments of the present invention, a channel may be formed by accumulation of a charge carrier, thus, electron mobility may be improved, thereby reducing resistance in the channel.

### BRIEF DESCRIPTION OF THE DRAWINGS

FIG. 1 is an exemplary cross-sectional view of a semiconductor device, according to an exemplary embodiment of the present invention.

FIGS. 2 to 7 are exemplary views sequentially illustrating a method of manufacturing the semiconductor device, according to the exemplary embodiment of the present invention.

FIG. 8 is an exemplary graph obtained by comparing breakdown voltages of the semiconductor device, according to the exemplary embodiment of the present invention and a semiconductor device in the related art.

FIG. 9 is an exemplary graph obtained by comparing electric field distributions of the semiconductor device, according to the exemplary embodiment of the present invention and the semiconductor device in the related art at the same voltage of 676 V.

FIG. 10 is an exemplary graph obtained by comparing on-resistances of the semiconductor device, according to the exemplary embodiment of the present invention and the semiconductor device in the related art.

### DETAILED DESCRIPTION OF THE EMBODIMENTS

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Hereinafter, exemplary embodiments of the present invention will be described in detail with reference to the accompanying drawings. As those skilled in the art would realize, the described embodiments may be modified in various different ways, all without departing from the spirit or scope of the present invention. On the contrary, exemplary embodiments introduced herein are provided to make disclosed contents thorough and complete and sufficiently transfer the spirit of the present invention to those skilled in the art.

In the drawings, the thickness of layers, films, panels, regions, etc., are exaggerated for clarity. It will be understood that when a layer is referred to as being “on” another layer or substrate, it may be directly on the other layer or substrate, or a space between the layers may be present. Like reference numerals designate like elements throughout the specification.

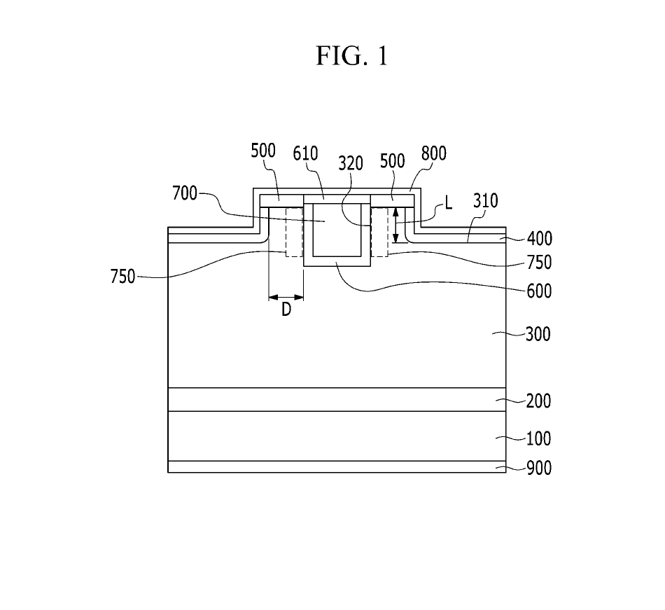

FIG. 1 is an exemplary cross-sectional view of a semiconductor device, according to an exemplary embodiment of the present invention.

Referring to FIG. 1, in the semiconductor device according to the present exemplary embodiment, an n type buffer layer 200 and an n− type epitaxial layer 300 are sequentially disposed on a first surface of an n+ type silicon carbide substrate 100.

A plurality of trenches include a first type of trench and a second type of trench. The first type of trench includes two trenches and the second type of trench includes one trench. The first type of trenches 310 and the second type of trench 320 are formed in the n− type epitaxial layer 300. The first type of trenches 310 are disposed at both sides of the second type of trench 320 and separated from the second type of trench 320 by a space D about 0.3 μm to 1 μm. in thickness

A p+ region 400 into which p+ ions such as boron (B) and aluminum (Al) are injected is formed in the first type of trenches 310. Additionally, a gate insulating layer 600 is formed in the second type of trench 320, and a gate material 700 is formed on the gate insulating layer 600. An oxidation layer 610 is formed on the gate material 700 and the gate insulating layer 600. The gate material 700 fills the second type of trench 320. The gate material 700 may be formed of metal or polycrystalline silicon. The gate insulating layer 600 and the oxidation layer 610 may be formed of silicon dioxide (SiO₂).

Furthermore, a plurality of n+ regions 500 into which n+ ions such as phosphorus (P), arsenic (As), and antimony (Sb) are injected are formed on the n− type epitaxial layer 300, and are disposed at both sides of the second type of trench 320. A space L between the lower surface of each n+ region 500 and the bottom surface of each first type of trenches 310 may be 1.5 μm or more. A channel 750 is formed by accumulation of the charge carriers at both sides of the second type of trench 320.

A source electrode 800 is formed on the p+ region 400, the n+ region 500, and the oxidation layer 610. A drain electrode 900 is formed on a second surface of the n+ type silicon carbide substrate 100. Furthermore, since the channel 750 is formed by accumulation of the charge carriers, a depth of the channel is increased, and thus an effect of an oxidation layer interface is reduced to improve electron mobility, thereby reducing resistance in the channel 750.

Further, it is possible to prevent a premature breakdown due to breakage of the gate insulating layer 600 and the oxidation layer 610 by adjusting the space between each first type of trench 310 and the second trench 320 to disperse an electric field concentrated on a lower portion of the gate material 700. Additionally, the premature breakdown means there is a breakdown voltage substantially lower than the breakdown voltage by an intrinsic threshold voltage of a raw material because of the breakdown when the oxidation layer is broken due to an electric field concentration effect in which the electric field is concentrated at a gate lower end in the trench gate.

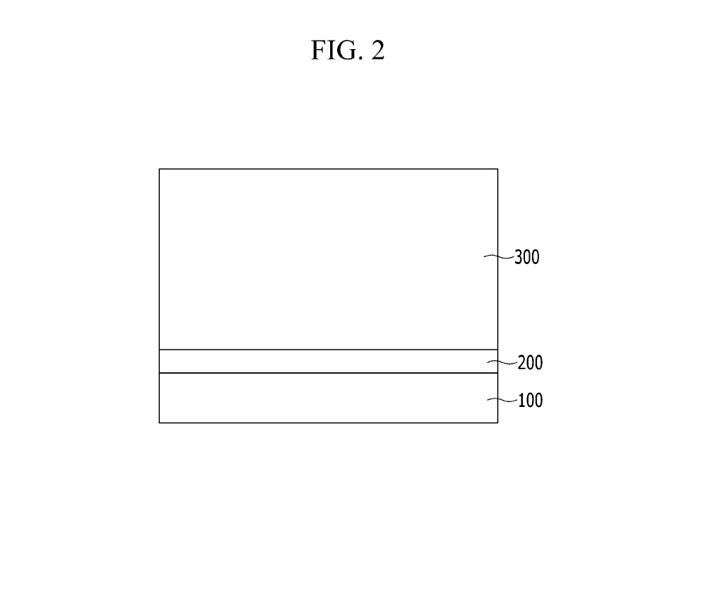

Moreover, referring to FIGS. 2 to 7 and FIG. 1, a method of manufacturing the semiconductor device, according to the exemplary embodiment of the present invention will be described in detail. FIGS. 2 to 7 are exemplary views illustrating a method of manufacturing the semiconductor device, according to the exemplary embodiment of the present invention.

As illustrated in FIG. 2, the n+ type silicon carbide substrate 100 is prepared, the n type buffer layer 200 is formed on the first surface of the n+ type silicon carbide substrate 100, and the n− type epitaxial layer 300 is formed on the n type buffer layer 200 by epitaxial growth.

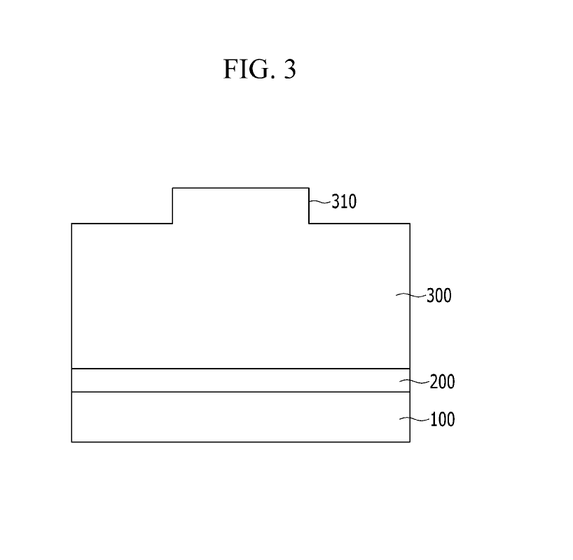

As illustrated in FIG. 3, a first type of trench 310 is formed in the n− type epitaxial layer 300, wherein the first type of trench includes two trenches.

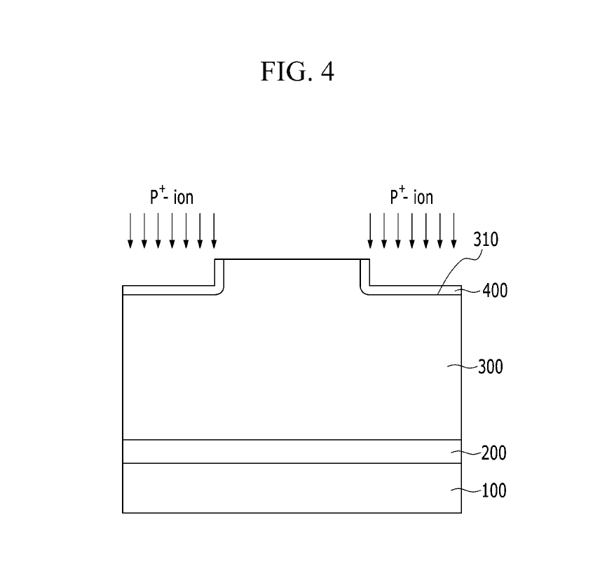

As illustrated in FIG. 4, p+ ions such as boron (B) and aluminum (Al) are injected into the first type of trenches 310 to form the p+ region 400.

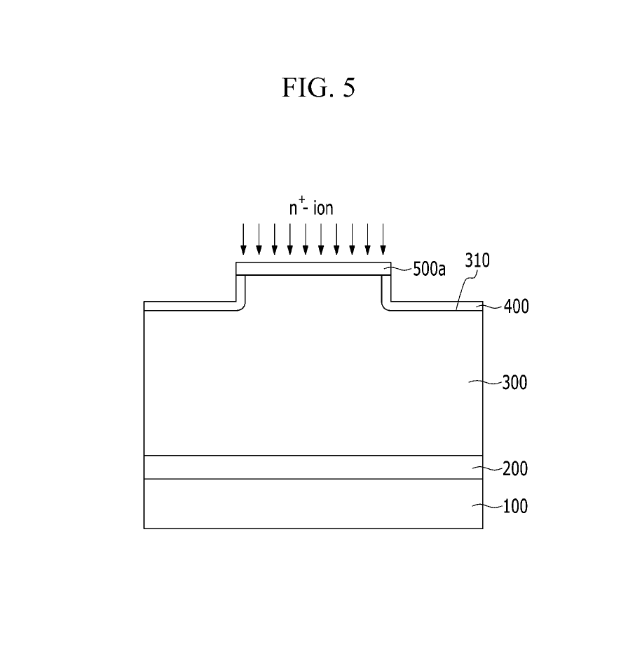

As illustrated in FIG. 5, a plurality of n+ ions such as phosphorus (P), arsenic (As), and antimony (Sb) are injected into the n− type epitaxial layer 300 to form a first n+ region 500a. In addition, the space between the lower surface of the n+ region 500 and the bottom surface of each first type of trench 310 may be 1.5 μm or more.

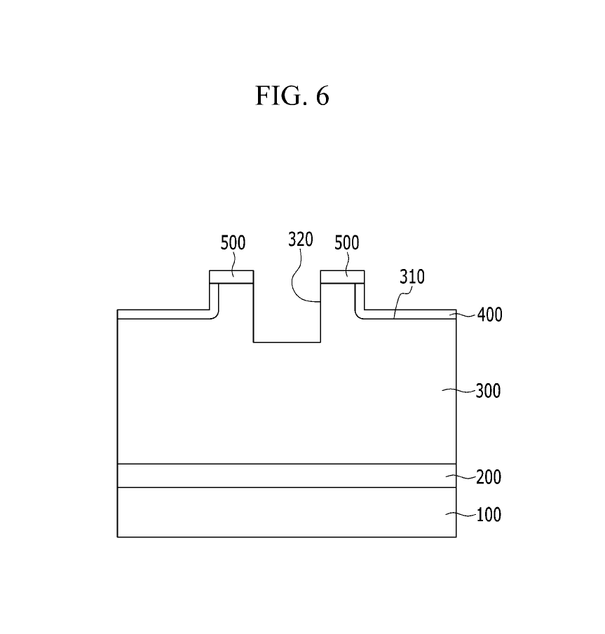

As illustrated in FIG. 6, a second type of trench 320, including one trench, is formed by etching a portion of the n− type epitaxial layer 300 through the first n+ region 500a. In particular, a portion of the first n+ region 500a is etched to form the n+ region 500. The second type of trench 320 is separated from the first type of trenches 310 by a space of 0.3 μm to 1 μm.

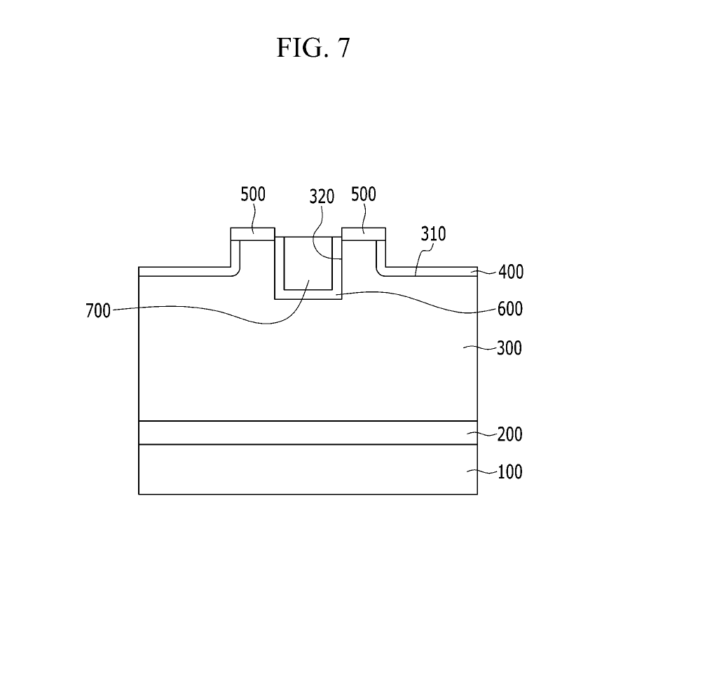

As illustrated in FIG. 7, the gate insulating layer 600 is formed in the second type of trench 320 using silicon dioxide (SiO₂), and the gate material 700 is formed on the gate insulating layer 600. In particular, the gate material 700 is formed to fill the second type of trench 320.

As illustrated in FIG. 1, the oxidation layer 610 is formed using silicon dioxide (SiO₂) covering the gate insulating layer 600 and the gate material 700, the source electrode 800 is formed on the p+ region 400, the oxidation layer 610, and the n+ region 500, and the drain electrode 900 is formed on the second surface of the n+ type silicon carbide substrate 100.

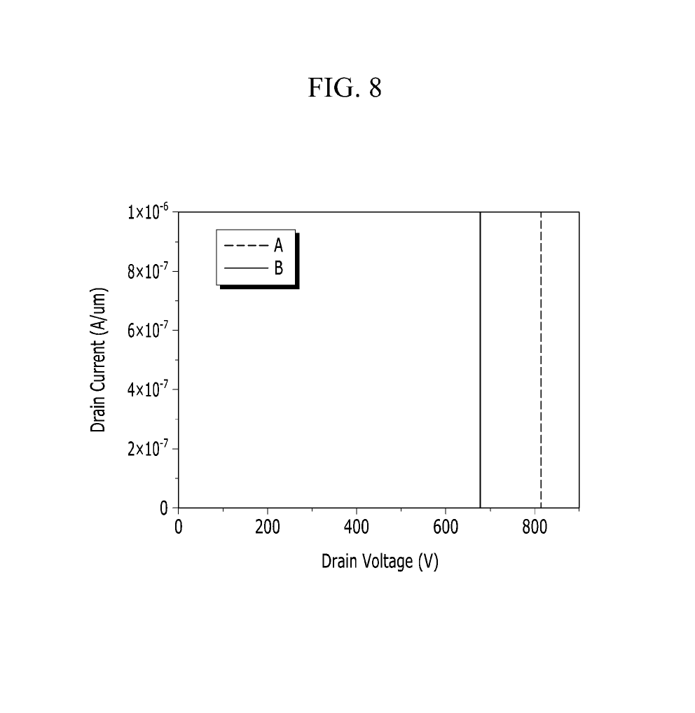

Referring to FIGS. 8 to 10, characteristics of the semiconductor device, according to the exemplary embodiment of the present invention and a semiconductor device in the related art will be described in detail. In FIGS. 8 to 10, A is the semiconductor device according to the exemplary embodiment of the present invention, and B is the semiconductor device in the related art.

FIG. 8 is an exemplary graph obtained by comparing breakdown voltages of the semiconductor device according to the exemplary embodiment of the present invention and the semiconductor device in the related art. The breakdown voltage of the semiconductor device in the related art is 676 V, and the breakdown voltage of the semiconductor device according to the exemplary embodiment of the present invention is 813 V. Thus, it can be seen that the breakdown voltage of the semiconductor device according to the exemplary embodiment of the present invention is increased by about 20%.

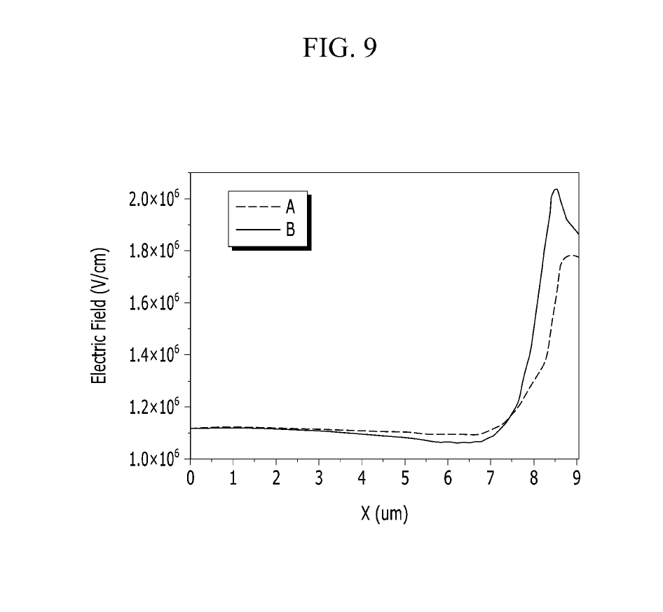

FIG. 9 is an exemplary graph obtained by comparing electric field distributions of the semiconductor device according to the exemplary embodiment of the present invention and the semiconductor device in the related art at the same voltage of 676 V. The graph illustrates that in the lower end of the gate material (e.g., x=8 to 9.05 μm), the electric field of the semiconductor device according to the exemplary embodiment of the present invention is lower than the electric field of the semiconductor device in the related art.

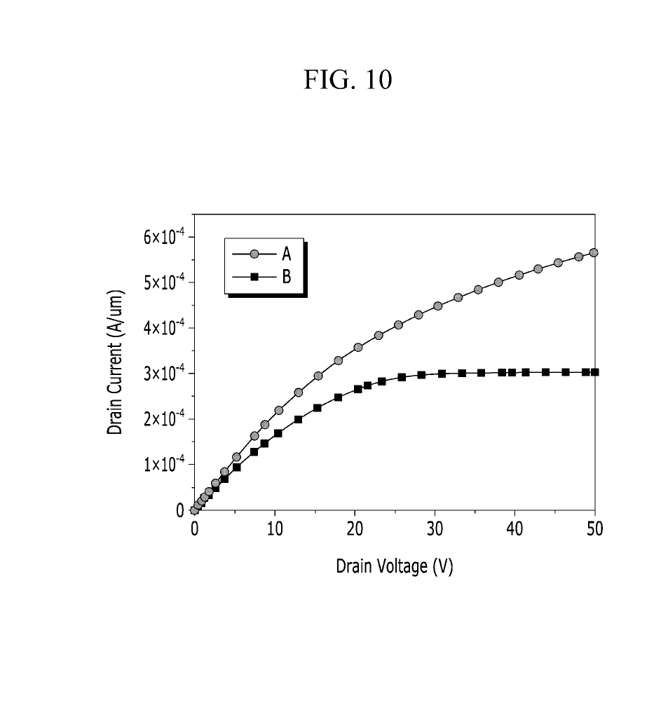

FIG. 10 is an exemplary graph obtained by comparing on-resistances of the semiconductor device according to the exemplary embodiment of the present invention and the semiconductor device in the related art. The on-resistance of the semiconductor device in the related art is 5.62 mΩ·cm², and the on-resistance of the semiconductor device according to the exemplary embodiment of the present invention is 4.19 mΩ·cm². Thus it can be seen that the on-resistance of the semiconductor device according to the exemplary embodiment of the present invention is decreased by about 23%.

While this invention has been described in connection with what is presently considered to be exemplary embodiments, it is to be understood that the invention is not limited to the disclosed embodiments, but, on the contrary, is intended to cover various modifications and equivalent arrangements included within the spirit and scope of the accompanying claims.

What is claimed is:

1. A semiconductor device comprising:
an n type buffer layer disposed on a first surface of an n+ type silicon carbide substrate;
an n− type epitaxial layer disposed on the n type buffer layer;
a plurality of trenches disposed in the n− type epitaxial layer, including a first type of trench and a second type of trench, wherein the first type of trench includes two trenches spaced from and disposed on each side of the second type of trench and the second type of trench includes one trench;
a plurality of n+ regions disposed on the n− type epitaxial layer;
a p+ region disposed in each first type of trench;
a gate insulating layer disposed in the second type of trench;
a gate material disposed on the gate insulating layer;
an oxidation layer disposed on the gate material;
a source electrode disposed on each n+ region, the oxidation layer, and the p+ region; and
a drain electrode disposed on a second surface of the n+ type silicon carbide substrate.

2. The semiconductor device of claim 1, wherein the space between each first type of trenches and the second type of trench is 0.3 μm to 1 μm.

3. The semiconductor device of claim 2, wherein a space between a lower surface of each first type of trench and the lower surface of each n+ region is 1.5 μm or more.

4. The semiconductor device of claim 1, wherein the plurality of n+ regions are disposed at both sides of the second type of trench.

5. The semiconductor device of claim 1, wherein a channel is formed adjacent to both sides of the second type of trench underneath each n+ region.

6. A method of manufacturing a semiconductor device, comprising:
forming an n type buffer layer on a first surface of an n+ type silicon carbide substrate;
forming an n− type epitaxial layer on the n type buffer layer;
forming a plurality of trenches in the n− type epitaxial layer, including a first type of trench and a second type of trench, wherein the first type of trench includes two trenches spaced form and disposed on each side of the second type of trench and the second type of trench includes one trench;
injecting a plurality of p+ ions into each first type of trench to form a p+ region;
injecting a plurality of n+ ions into the n− type epitaxial layer to form a plurality of n+ regions;
etching a portion of the n− type epitaxial layer formed through the first n+ region to form the second type of trench;
forming a gate insulating layer in the second type of trench;
forming a gate material on the gate insulating layer;
forming an oxidation layer on the gate material;
forming a drain electrode on a second surface of the n+ type silicon carbide substrate; and
forming a source electrode on the p+ region, each n+ region, and the oxidation layer.

7. The method of manufacturing a semiconductor device of claim 6, wherein each of the first type of trenches is separated from the second type of trench by a space of 0.3 μm to 1 μm.

8. The method of manufacturing a semiconductor device of claim 7, wherein a space between a lower surface of each first trench and the lower surface of the n+ region is 1.5 μm or more.

9. The method of manufacturing a semiconductor device of claim 6, further comprising forming a channel adjacent to both sides of the second type of trench underneath each n+ region.
